(19) United States
(12) Patent Application Publication
(10) Pub. No.: US 2026/0007051 A1
(43) Pub. Date: Jan. 1, 2026

(54) DISPLAY DEVICE AND MOBILE ELECTRONIC DEVICE INCLUDING THE SAME

(71) Applicant: Samsung Display Co., LTD., Yongin-si (KR)

(72) Inventor: Ji Won LEE, Yongin-si (KR)

(21) Appl. No.: 19/083,209

(22) Filed: Mar. 18, 2025

(30) Foreign Application Priority Data
Jun. 26, 2024 (KR) 10-2024-0083806
Oct. 23, 2024 (KR) 10-2024-0145614

(51) Int. Cl. H10K 59/80; G02B 27/01; H10H 29/80; H10H 29/855

(52) U.S. Cl. CPC H10K 59/879; H10H 29/842; H10H 29/855; H10K 59/878; H10K 59/8793; G02B 27/0172; G02B 2027/0178

(57) ABSTRACT

A display device and a mobile electronic device are provided. The display device includes a display panel, which includes a display element layer including a light emitting element, an encapsulation layer on the display element layer, and an optical layer on the encapsulation layer, the optical layer including a plurality of lenses, and a pancake lens unit on the display panel, the pancake lens unit including at least one first pancake lens element including a plastic material and at least one second pancake lens element including a glass material.

### CROSS-REFERENCE TO RELATED APPLICATION

The present application claims priority to and the benefit of Korean Patent Application No. 10-2024-0083806, filed on Jun. 26, 2024, in the Korean Intellectual Property Office, and Korean Patent Application No. 10-2024-0145614, filed on Oct. 23, 2024, in the Korean Intellectual Property Office, the entire disclosures of both of which are incorporated by reference herein.

### BACKGROUND

### 1. Field

The present disclosure relates to a display device and a mobile electronic device including the same.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of at least 2000 pixels per inch (PPI) so that a user can use it for a long time without dizziness. To this end, organic light emitting diode on silicon (OLEDoS) technology, which is a small high-resolution organic light emitting display device, is being proposed. OLEDOS is a technology for placing an organic light emitting diode (OLED) on a semiconductor wafer substrate on which a complementary metal oxide semiconductor (CMOS) is disposed.

### SUMMARY

Aspects and features of embodiments of the present disclosure provide a display device capable of increasing light efficiency and a mobile electronic device including the display device.

Aspects and features of embodiments of the present disclosure also provide a display device capable of reducing a thickness of an optical module and a mobile electronic device including the display device.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a display panel, which includes a display element layer including a light emitting element, an encapsulation layer on the display element layer, and an optical layer on the encapsulation layer, the optical layer including a plurality of lenses, and a pancake lens unit on the display panel, the pancake lens unit including at least one first pancake lens element including a plastic material and at least one second pancake lens element including a glass material.

In one or more embodiments, the at least one first pancake lens element is between the display panel and the at least one second pancake lens element.

In one or more embodiments, the at least one first pancake lens element comprises a first pancake lens and a second pancake lens overlapping each other.

In one or more embodiments, a material of each of the first pancake lens and the second pancake lens comprises at least one of polyester-based plastic and cyclo olefin polymer (COP)-based plastic.

In one or more embodiments, the at least one second pancake lens element comprises a third pancake lens and a fourth pancake lens overlapping each other.

In one or more embodiments, a half mirror is located between the third pancake lens and the fourth pancake lens.

In one or more embodiments, a material of each of the third pancake lens and the fourth pancake lens comprises glass having a refractive index of about 1.9 or more.

In one or more embodiments, a first anti-reflection film, a first quarter-wave plate (QWP), a first polarizing film, and a second QWP are between the at least one first pancake lens element and the at least one second pancake lens element.

In one or more embodiments, a third QWP, a second polarizing film, a third polarizing film, and a second anti-reflection film are on the at least one second pancake lens element.

In one or more embodiments, the second polarizing film is a reflective polarizing film, and the third polarizing film is an absorbing polarizing film.

According to one or more embodiments of the present disclosure, there is provided a mobile electronic device including a display panel, which includes a display element layer including a light emitting element, an encapsulation layer on the display element layer, and an optical layer on the encapsulation layer, the optical layer including a plurality of lenses, and a pancake lens unit on the display panel, the pancake lens unit including at least one first pancake lens element including a plastic material and at least one second pancake lens element including a glass material.

In one or more embodiments, the at least one first pancake lens element is between the display panel and the at least one second pancake lens element.

In one or more embodiments, the at least one first pancake lens element comprises a first pancake lens and a second pancake lens overlapping each other.

In one or more embodiments, a material of each of the first pancake lens and the second pancake lens comprises at least one of polyester-based plastic and cyclo olefin polymer (COP)-based plastic.

In one or more embodiments, the at least one second pancake lens element comprises a third pancake lens and a fourth pancake lens overlapping each other.

In one or more embodiments, a half mirror is located between the third pancake lens and the fourth pancake lens.

In one or more embodiments, a material of each of the third pancake lens and the fourth pancake lens comprises glass having a refractive index of about 1.9 or more.

In one or more embodiments, a first anti-reflection film, a first QWP, a first polarizing film, and a second QWP are between the at least one first pancake lens element and the at least one second pancake lens element.

In one or more embodiments, a third QWP, a second polarizing film, a third polarizing film, and a second anti-reflection film are on the at least one second pancake lens element.

In one or more embodiments, the second polarizing film is a reflective polarizing film, and the third polarizing film is an absorbing polarizing film.

According to one or more embodiments, in a display device and a mobile electronic device including the same, light efficiency can be increased.

In addition, in the display device and the mobile electronic device including the same according to one or more embodiments, a thickness of an optical module can be reduced.

However, the effects, aspects, and features of the present disclosure are not restricted to the one set forth herein. The above and other effects, aspects, and features, of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to one or more embodiments;

FIG. 2 is a block diagram of the display device according to one or more embodiments;

FIG. 3 is an equivalent circuit diagram of a first subpixel according to one or more embodiments;

FIG. 4 is a layout view of an example of a display panel according to one or more embodiments;

FIGS. 5 and 6 are layout views of embodiments of a display area of FIG. 4;

FIG. 7 is a cross-sectional view of an example of the display panel, taken along the line 11-11′ of FIG. 5;

FIG. 8 is a perspective view of a head mounted display device according to one or more embodiments;

FIG. 9 is an exploded perspective view of an example of the head mounted display device of FIG. 8;

FIG. 10 is a perspective view of a head mounted display device according to one or more embodiments;

FIG. 11 illustrates the configuration of a display device including a pancake lens unit according to one or more embodiments;

FIG. 12 illustrates the configuration of the pancake lens unit according to one or more embodiments; and

FIG. 13 illustrates the stacked structure of the pancake lens unit according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

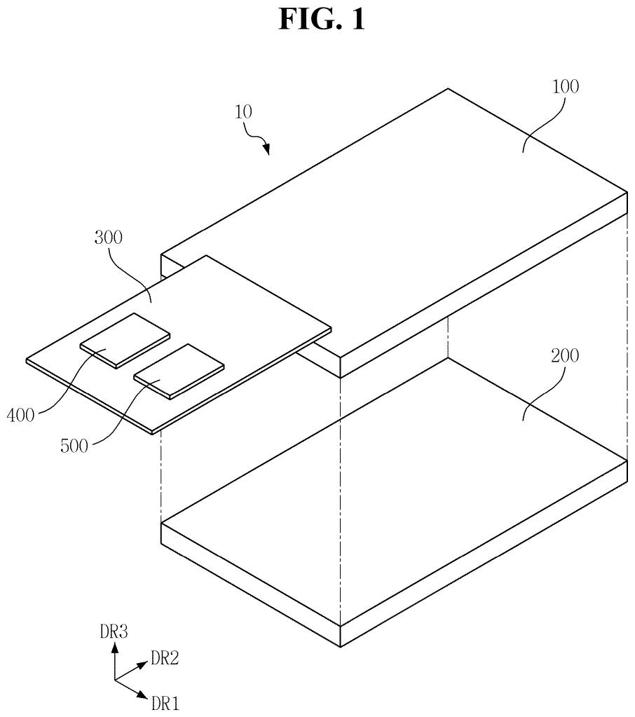

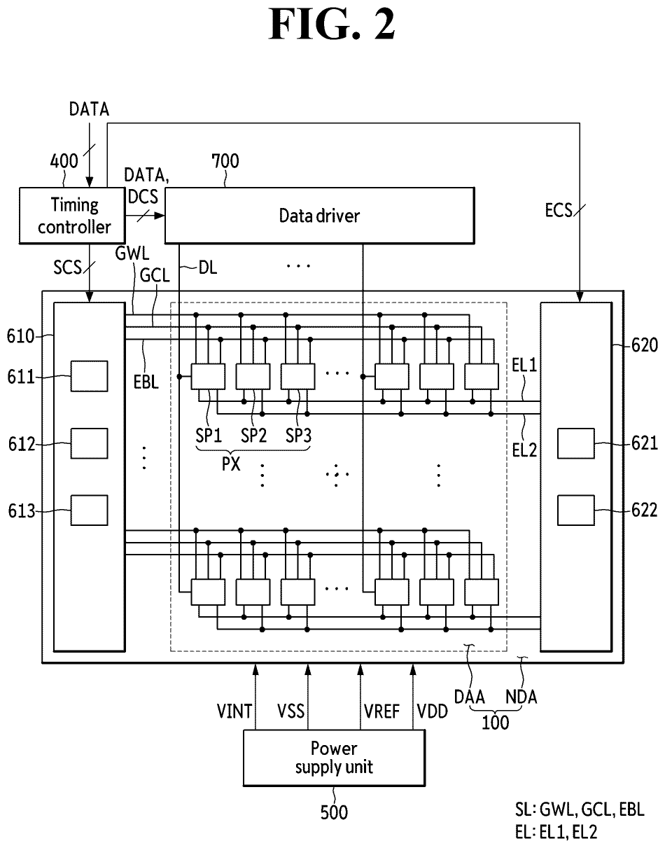

FIG. 1 is an exploded perspective view of a display device 10 according to one or more embodiments. FIG. 2 is a block diagram of the display device 10 according to one or more embodiments.

Referring to FIGS. 1 and 2, the display device 10 according to one or more embodiments is a device for displaying moving images and/or still images. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to one or more embodiments may be applied as a display unit of a television, a notebook computer, a monitor, a billboard, and/or an Internet of things (loT) device. Alternatively, the display device 10 according to one or more embodiments may be applied to smart watches, watch phones, and head mounted displays (HMDs) for implementing virtual reality and augmented reality.

The display device 10 according to one or more embodiments includes a display panel 100, a heat dissipation layer 200, a circuit board 300, a timing controller 400, and a power supply unit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape and may also be similar to other polygonal shapes, a circular shape, and/or an oval shape. The planar shape of the display device 10 may follow the planar shape of the display panel 100, but the present disclosure is not limited thereto.

As illustrated in FIG. 2, the display panel 100 includes a display area DAA that displays an image and a non-display area NDA that does not display an image.

The display area DAA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix form along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1.

The scan lines SL may include a plurality of write scan lines GWL, a plurality of control scan lines GCL, and a plurality of bias scan lines EBL. The emission control lines EL may include a plurality of first emission control lines EL1 and a plurality of second emission control lines EL2.

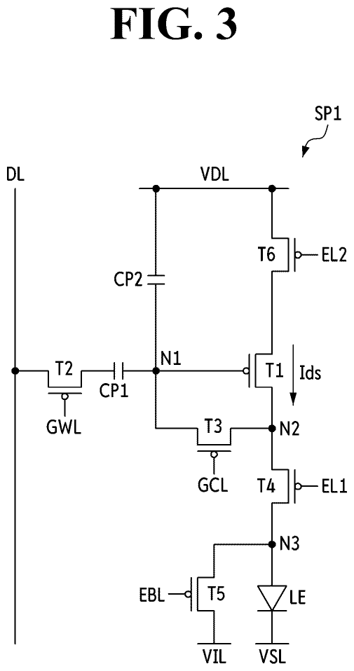

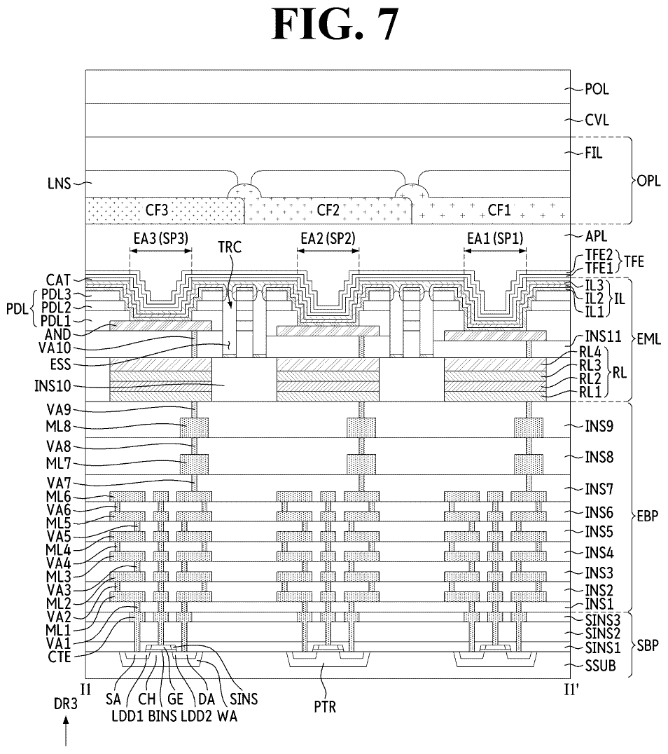

Each of the pixels PX includes a plurality of subpixels SP1 through SP3. Each of the subpixels SP1 through SP3 includes a plurality of pixel transistors as illustrated in FIG. 3. The pixel transistors may be formed through a semiconductor process and may be disposed on a semiconductor substrate SSUB (see FIG. 7). For example, a plurality of pixel transistors of a data driver 700 may be formed as complementary metal oxide semiconductor (CMOS) transistors.

Each of the subpixels SP1 through SP3 may be connected to one of the write scan lines GWL, one of the control scan lines GCL, one of the bias scan lines EBL, one of the first emission control lines EL1, one of the second emission control lines EL2, and one of the data lines DL. Each of the subpixels SP1 through SP3 may receive a data voltage of a data line DL according to a write scan signal of a write scan line GWL and emit light from a light emitting element according to the data voltage.

The non-display area NDA includes a scan driver 610, an emission driver 620, and the data driver 700.

The scan driver 610 includes a plurality of scan transistors, and the emission driver 620 includes a plurality of emission transistors. The scan transistors and the emission transistors may be formed through a semiconductor process and may be formed on the semiconductor substrate SSUB (see FIG. 7). For example, the scan transistors and the emission transistors may be formed as CMOS transistors. In FIG. 2, the scan driver 610 is disposed on a left side of the display area DAA, and the emission driver 620 is disposed on a right side of the display area DAA. However, the present disclosure is not limited thereto. For example, the scan driver 610 and the emission driver 620 may also be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driving unit 621 and a second emission control driving unit 622. Each of the first emission control driving unit 621 and the second emission control driving unit 622 may receive an emission timing control signal ECS from the timing controller 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 includes a plurality of data transistors. The data transistors may be formed through a semiconductor process and may be formed on the semiconductor substrate SSUB (see FIG. 7). For example, the data transistors may be formed as CMOS transistors.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be disposed on a surface, e.g., a back surface of the display panel 100. The heat dissipation layer 200 dissipates heat generated from the display panel 100. The heat dissipation layer 130 may include a metal layer having high thermal conductivity, such as graphite, silver (Ag), copper (Cu), and/or aluminum (AI).

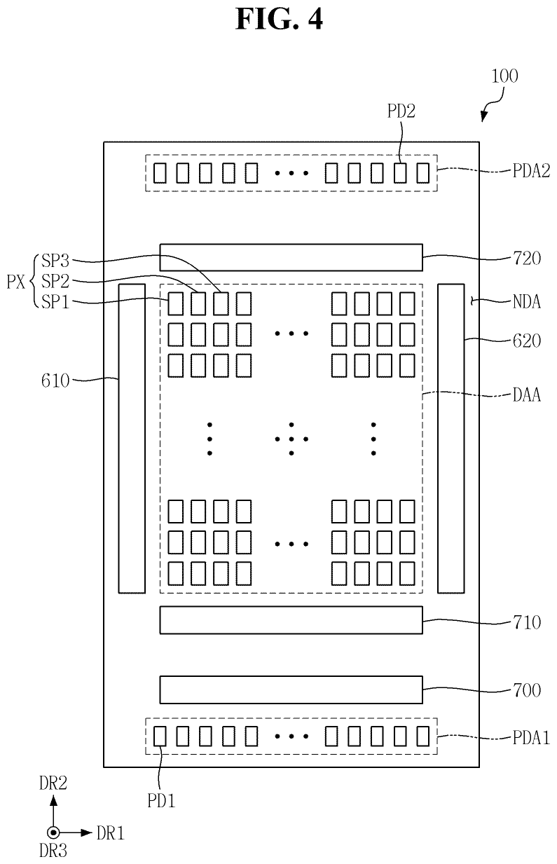

The circuit board 300 may be electrically connected to a plurality of first pads PD1 (see FIG. 4) in a first pad portion PDA1 (see FIG. 4) of the display panel 100 by using a conductive adhesive member such as an anisotropic conductive film. The circuit board 300 may be a flexible printed circuit board (FPCB) made of a flexible material and/or may be a flexible film. Although the circuit board 300 is unfolded in FIG. 1, it may also be bent. In this case, one end of the circuit board 300 may be placed on the back surface of the display panel 100 and/or a back surface of the heat dissipation layer 200. The end of the circuit board 300 may be an end opposite the other end of the circuit board 300 which is connected to the first pads PD1 (see FIG. 4) in the first pad portion PDA1 (see FIG. 4) of the display panel 100 by using the conductive adhesive member.

The timing controller 400 may receive the digital video data DATA and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and the emission timing control signal ECS to the emission driver 620. The timing controller 400 may output the digital video data DATA and the data timing control signal DCS to the data driver 700.

The power supply unit 500 may generate a plurality of panel driving voltages according to a power supply voltage received from the outside. For example, the power supply unit 500 may generate a first driving voltage VSS, a second driving voltage VDD, a third driving voltage VINT, and a reference voltage VREF and supply them to the display panel 100. The first driving voltage VSS, the second driving voltage VDD, and the third driving voltage VINT will be described later with reference to FIG. 3.

Each of the timing controller 400 and the power supply unit 500 may be formed as an integrated circuit (IC) and attached to a surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

Alternatively, each of the timing controller 400 and the power supply unit 500 may be disposed in the non-display area NDA of the display panel 100, like the scan driver 610, the emission driver 620, and the data driver 700. In this case, the timing controller 400 may include a plurality of timing transistors, and the power supply unit 500 may include a plurality of power transistors. The timing transistors and the power transistors may be formed through a semiconductor process and may be formed on the semiconductor substrate SSUB (see FIG. 7). For example, the timing transistors and the power transistors may be formed as CMOS transistors. Each of the timing controller 400 and the power supply unit 500 may be disposed between the data driver 700 and the first pad portion PDA1 (see FIG. 4).

FIG. 3 is an equivalent circuit diagram of a first subpixel SP1 according to one or more embodiments.

Referring to FIG. 3, the first subpixel SP1 may be connected to a write scan line GWL, a control scan line GCL, a bias scan line EBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

The first subpixel SP1 includes a plurality of transistors T1 through T6, a light emitting element LE, a first capacitor CP1, and a second capacitor CP2.

The light emitting element LE emits light according to a driving current Ids flowing through a channel of a first transistor T1. The amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. The light emitting element LE may be an organic light emitting diode (OLED) including a first electrode, a second electrode, and an organic light emitting layer disposed between the first electrode and the second electrode. However, the present disclosure is not limited thereto. For example, the light emitting element LE may be an inorganic light emitting element including a first electrode, a second electrode, and an inorganic semiconductor disposed between the first electrode and the second electrode. In this case, the light emitting element LE may be a micro light emitting diode.

The first transistor T1 may be a driving transistor that controls a source-drain current Ids (hereinafter, referred to as a “driving current”) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 is turned on by a write scan signal of the write scan line GWL to connect the electrode of the first capacitor CP1 to the data line DL. Accordingly, a data voltage of the data line DL may be applied to the electrode of the first capacitor CP1. The second transistor T2 includes a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 is turned on by a write control signal of the write control line GCL to connect the first node N1 to the second node N2. Accordingly, because the gate electrode and source electrode of the first transistor T1 are connected, the first transistor T1 may operate as a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 is turned on by a bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 (or the first node N1) and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, the present disclosure is not limited thereto. Each of the first through sixth transistors T1 through T6 may also be an N-type MOSFET. Alternatively, some of the first through sixth transistors T1 through T6 may be P-type MOSFETs, and the other transistors may be N-type MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors of the first subpixel SP1 are not limited to those illustrated in FIG. 3.

In addition, an equivalent circuit diagram of a second subpixel SP2 and an equivalent circuit diagram of a third subpixel SP3 may be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the present specification.

FIG. 4 is a layout view of an example of a display panel 100 according to one or more embodiments.

Referring to FIG. 4, a display area DAA of the display panel 100 according to one or more embodiments includes a plurality of pixels PX arranged in a matrix form. A non-display area NDA of the display panel 100 according to one or more embodiments includes a scan driver 610, an emission driver 620, a data driver 700, a first distribution circuit 710, a second distribution circuit 720, a first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on a left side of the display area DAA, and the emission driver 620 may be disposed on a right side of the display area DAA. However, the present disclosure is not limited thereto, and the scan driver 610 and the emission driver 620 may also be disposed on both the first and second sides of the display area DAA.

The first pad portion PDA1 may include a plurality of first pads PD1 connected to pads or bumps of the circuit board 300 through a conductive adhesive member. The first pad portion PDA1 may be disposed on a third side of the display area DAA. For example, the first pad portion PDA1 may be disposed on one side of the display area DAA in the second direction DR2. That is, the first pad portion PDA1 may be disposed on a lower side of the display area DAA.

The first pad portion PDA1 may be disposed outside the data driver 700 in the second direction DR2. That is, the first pad portion PDA1 may be disposed closer to an edge of the display panel 100 than the data driver 700 is.

The second pad portion PDA2 may include a plurality of second pads PD2 corresponding to test pads for testing whether the display panel 100 operates normally. The second pads PD2 may be connected to a jig or a probe pin during a test process or may be connected to a test circuit board. The test circuit board may be a printed circuit board (PCB) made of a rigid material or a flexible printed circuit board (FPCB) made of a flexible material.

The first distribution circuit 710 distributes data voltages received through the first pad portion PDA1 to a plurality of data lines DL. For example, the first distribution circuit 710 may distribute data voltages received through one first pad PD1 of the first pad portion PDA1 to P (P is a positive integer of 2 or more) data lines DL. Therefore, the number of first pads PD1 can be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals received through the second pad portion PDA2 to the scan driver 610, the emission driver 620, and the data lines DL. The second pad portion PDA2 and the second distribution circuit 720 may be elements for testing the operation of each of the pixels PX in the display area DAA. The second distribution circuit 720 may be disposed on a fourth side of the display area DAA of the display panel 100. For example, the second distribution circuit 720 may be disposed on the other side of the display area DAA in the second direction DR2. That is, the second distribution circuit 720 may be disposed on an upper side of the display area DAA.

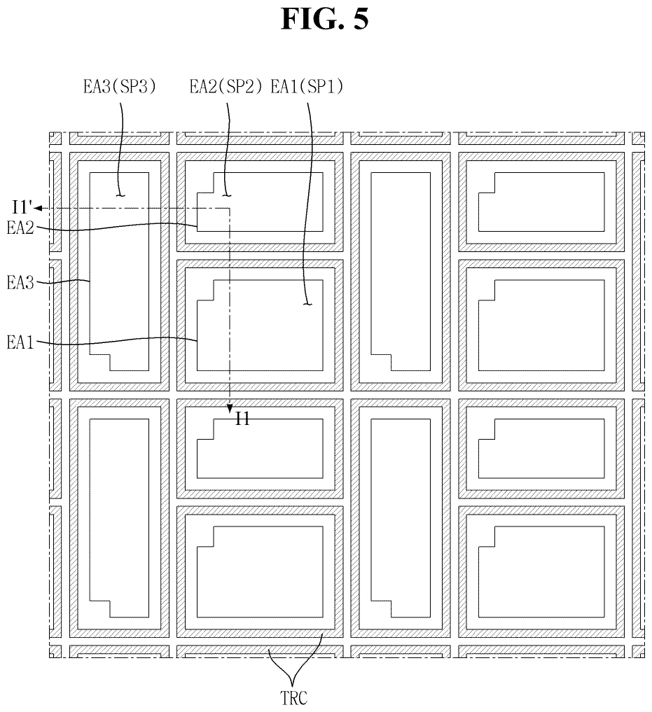

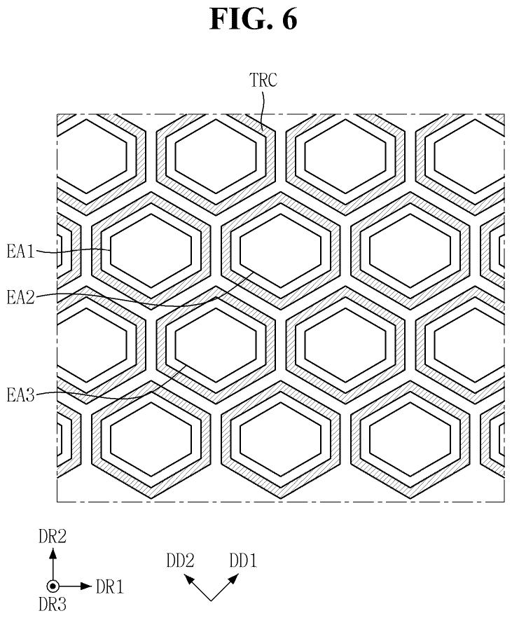

FIGS. 5 and 6 are layout views of one or more embodiments of the display area DAA of FIG. 4.

Referring to FIGS. 5 and 6, each of a plurality of pixels PX includes a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular planar shape.

A maximum length of the third emission area EA3 in the first direction DR1 may be smaller than a maximum length of the second emission area EA2 in the first direction DR1 and a maximum length of the first emission area EA1 in the first direction DR1. The maximum length of the second emission area EA2 in the first direction DR1 may be substantially the same as the maximum length of the first emission area EA1 in the first direction DR1.

A maximum length of the third emission area EA3 in the second direction DR2 may be greater than a maximum length of the second emission area EA2 in the second direction DR2 and a maximum length of the first emission area EA1 in the second direction DR2. The maximum length of the second emission area EA2 in the second direction DR2 may be smaller than the maximum length of the third emission area EA3 in the second direction DR2. The maximum length of the first emission area EA1 may be greater than the maximum length of the second emission area EA2 in the second direction DR2.

The first emission area EA1, the second emission area EA2, and the third emission area EA3 may have a hexagonal planar shape composed of six straight lines as illustrated in FIGS. 5 and 6. However, the present disclosure is not limited thereto. The first emission area EA1, the second emission area EA2, and the third emission area EA3 may also have a polygonal planar shape other than a hexagonal shape or may have a circular, oval or irregular planar shape.

As illustrated in FIG. 5, in each of the pixels PX, the first emission area EA1 and the second emission area EA2 may neighbor each other in the second direction DR2. In addition, the first emission area EA1 and the third emission area EA3 may neighbor each other in the first direction DR1. In addition, the second emission area EA2 and the third emission area EA3 may neighbor each other in the first direction DR1. The area of the first emission area EA1, the area of the second emission area EA2, and the area of the third emission area EA3 may be different.

Alternatively, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined at 45 degrees with respect to the first direction DR1 and the second direction DR2. The second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Although each of the pixels PX includes three emission areas EA1 through EA3 in FIGS. 5 and 6, the present disclosure is not limited thereto. That is, each of the pixels PX may also include four emission areas.

In addition, the arrangement of the emission areas of the pixels PX is not limited to those illustrated in FIGS. 5 and 6. For example, the emission areas of the pixels PX may also be arranged in a stripe structure in which emission areas are arranged along the first direction DR1, in a PENTILE® structure in which emission areas are arranged in a diamond shape, or in a hexagonal structure in which emission areas having a hexagonal planar shape are arranged as illustrated in FIG. 6. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

FIG. 7 is a cross-sectional view of an example of the display panel 100, taken along the line 11-11′ of FIG. 5.

Referring to FIG. 7, the display panel 100 includes a semiconductor backplane SBP, a light emitting element backplane EBP, a display element layer EML, an encapsulation layer TFE, organic layer APL, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to each of the pixel transistors PTR. The pixel transistors PTR may be the first through sixth transistors T1 through T6 described with reference to FIG. 3.

The semiconductor substrate SSUB may be a silicon substrate, a germanium substrate, or a silicon-germanium substrate. The semiconductor substrate SSUB may be a substrate doped with a first-type impurity. A plurality of well areas WA may be disposed in an upper surface of the semiconductor substrate SSUB. The well areas WA may be areas doped with a second-type impurity. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the well areas WA includes a source area SA corresponding to a source electrode of a pixel transistor PTR, a drain area DA corresponding to a drain electrode of the pixel transistor PTR, and a channel area CH disposed between the source area SA and the drain area DA.

A bottom insulating layer BINS may be disposed between a gate electrode GE and each well area WA. A side insulating layer SINS may be disposed on side surfaces of the gate electrode GE. The side insulating layer SINS may be disposed on the bottom insulating layer BINS.

Each of the source area SA and the drain area DA may be an area doped with the first-type impurity. The gate electrode GE of each pixel transistor PTR may overlap a well area WA in the third direction DR3. The channel area CH may overlap the gate electrode GE in the third direction DR3. The source area SA may be disposed on one side of the gate electrode GE, and the drain area DA may be disposed on the other side of the gate electrode GE.

Each of the well areas WA further includes a first lightly doped impurity area LDD1 disposed between the channel area CH and the source area SA and a second lightly doped impurity area LDD2 disposed between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be disposed on the semiconductor substrate SSUB. The first semiconductor insulating layer SINS1 may be a silicon carbon nitride (SiCN) and/or silicon oxide (SiOx)-based inorganic layer, but the present disclosure is not limited thereto.

A second semiconductor insulating layer SINS2 may be disposed on the first semiconductor insulating layer SINS1. The second semiconductor insulating layer SINS2 may be a silicon oxide (SiOx)-based inorganic layer, but the present disclosure is not limited thereto.

The contact terminals CTE may be disposed on the second semiconductor insulating layer SINS2. Each of the contact terminals CTE may be connected to one of the gate electrode GE, the source area SA, and the drain area DA of a pixel transistor PTR through a hole penetrating the first semiconductor insulating layer SINS1 and the second semiconductor insulating layer SINS2. The contact terminals CTE may be made of copper (Cu), aluminum (AI), tungsten (W), molybdenum (Mo), chromium (Cr), gold (Au), titanium (Ti), nickel (Ni) and/or neodymium (Nd) or may be made of an alloy including one or more of the same.

A third semiconductor insulating layer SINS3 may be disposed on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOx)-based inorganic layer, but the present disclosure is not limited thereto.

The semiconductor substrate SSUB can be replaced with a glass substrate or a polymer resin substrate such as polyimide. In this case, thin-film transistors may be disposed on the glass substrate or the polymer resin substrate. The glass substrate may be a rigid substrate that is not bent, and the polymer resin substrate may be a flexible substrate that can be bent or curved.

The light emitting element backplane EBP includes a plurality of conductive layers ML1 through ML8, a plurality of vias VA1 through VA9, and a plurality of insulating layers INS1 through INS9. In addition, the light emitting element backplane EBP includes a plurality of insulating layers INS1 through INS9 disposed between first through eighth conductive layers ML1 through ML8.

The first through eighth conductive layers ML1 through ML8 implement the circuit of the first subpixel SP1 illustrated in FIG. 3 by connecting the contact terminals CTE exposed in the semiconductor backplane SBP. For example, the first through sixth transistors T1 through T6 are only formed in the semiconductor backplane SBP, and the connection of the first through sixth transistors T1 through T6 and the connection of the first and second capacitors CP1 and CP2 are achieved through the first through eighth conductive layers ML1 through ML8. In addition, the connection between a drain area corresponding to the drain electrode of the fourth transistor T4, a source area corresponding to the source electrode of the fifth transistor T5, and the first electrode of the light emitting element LE is achieved through the first through eighth conductive layers ML1 through ML8.

A first insulating layer INS1 may be disposed on the semiconductor backplane SBP. Each of first vias VA1 may penetrate the first insulating layer INS1 and may be connected to a contact terminal CTE exposed in the semiconductor backplane SBP. Each of the first conductive layers ML1 may be disposed on the first insulating layer INS1 and may be connected to a first via VA1.

A second insulating layer INS2 may be disposed on the first insulating layer INS1 and the first conductive layers ML1. Each of second vias VA2 may penetrate the second insulating layer INS2 and may be connected to an exposed first conductive layer ML1. Each of the second conductive layers ML2 may be disposed on the second insulating layer INS2 and may be connected to a second via VA2.

A third insulating layer INS3 may be disposed on the second insulating layer INS2 and the second conductive layers ML2. Each of third vias VA3 may penetrate the third insulating layer INS3 and may be connected to an exposed second conductive layer ML2. Each of the third conductive layers ML3 may be disposed on the third insulating layer INS3 and may be connected to a third via VA3.

A fourth insulating layer INS4 may be disposed on the third insulating layer INS3 and the third conductive layers ML3. Each of fourth vias VA4 may penetrate the fourth insulating layer INS4 and may be connected to an exposed third conductive layer ML3. Each of the fourth conductive layers ML4 may be disposed on the fourth insulating layer INS4 and may be connected to a fourth via VA4.

A fifth insulating layer INS5 may be disposed on the fourth insulating layer INS4 and the fourth conductive layers ML4. Each of fifth vias VA5 may penetrate the fifth insulating layer INS5 and may be connected to an exposed fourth conductive layer ML4. Each of the fifth conductive layers ML5 may be disposed on the fifth insulating layer INS5 and may be connected to a fifth via VA5.

A sixth insulating layer INS6 may be disposed on the fifth insulating layer INS5 and the fifth conductive layers ML5. Each of sixth vias VA6 may penetrate the sixth insulating layer INS6 and may be connected to an exposed fifth conductive layer ML5. Each of the sixth conductive layers ML6 may be disposed on the sixth insulating layer INS6 and may be connected to a sixth via VA6.

A seventh insulating layer INS7 may be disposed on the sixth insulating layer INS6 and the sixth conductive layers ML6. Each of seventh vias VA7 may penetrate the seventh insulating layer INS7 and may be connected to an exposed sixth conductive layer ML6. Each of the seventh conductive layers ML7 may be disposed on the seventh insulating layer INS7 and may be connected to a seventh via VA7.

An eighth insulating layer INS8 may be disposed on the seventh insulating layer INS7 and the seventh conductive layers ML7. Each of eighth vias VA8 may penetrate the eighth insulating layer INS8 and may be connected to an exposed seventh conductive layer ML7. Each of the eighth conductive layers ML8 may be disposed on the eighth insulating layer INS8 and may be connected to an eighth via VA8.

The first through eighth conductive layers ML1 through ML8 and the first through eighth vias VA1 through VA8 may be made of substantially the same material. The first through eighth conductive layers ML1 through ML8 and the first through eighth vias VA1 through VA8 may be made of (Cu), aluminum (AI), tungsten (W), molybdenum (Mo), chromium (Cr), gold (Au), titanium (Ti), nickel (Ni) and/or neodymium (Nd) and/or may be made of an alloy including one or more of the same. The first through eighth vias VA1 through VA8 may be made of substantially the same material. Each of the first through eighth insulating layers INS1 through INS8 may be a silicon oxide (SiOx)-based inorganic layer, but the present disclosure is not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than each of a thickness of the first vias VA1, a thickness of the second vias VA2, a thickness of the third vias VA3, a thickness of the fourth vias VA4, a thickness of the fifth vias VA5, and a thickness of the sixth vias VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layers ML1 may be about 1360 Å, and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be about 1440 Å. In addition, the thickness of the first vias VA1, the thickness of the second vias VA2, the thickness of the third vias VA3, the thickness of the fourth vias VA4, the thickness of the fifth vias VA5, and the thickness of the sixth vias VA6 may each be about 1150 Å.

A thickness of the seventh conductive layers ML7 and a thickness of the eighth conductive layers ML8 may each be greater than each of the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6. The thickness of the seventh conductive layers ML7 and the thickness of the eighth conductive layers ML8 may each be greater than each of a thickness of the seventh vias VA7 and a thickness of the eighth vias VA8. The thickness of the seventh vias VA7 and the thickness of the eighth vias VA8 may each be greater than each of the thickness of the first vias VA1, the thickness of the second vias VA2, the thickness of the third vias VA3, the thickness of the fourth vias VA4, the thickness of the fifth vias VA5, and the thickness of the sixth vias VA6. The thickness of the seventh conductive layers ML7 and the thickness of the eighth conductive layers ML8 may be substantially the same. For example, the thickness of the seventh conductive layers ML7 and the thickness of the eighth conductive layers ML8 may each be about 9000 Å. The thickness of the seventh vias VA7 and the thickness of the eighth vias VA8 may each be about 6000 Å.

A ninth insulating layer INS9 may be disposed on the eighth insulating layer INS8 and the eighth conductive layers ML8. The ninth insulating layer INS9 may be a silicon oxide (SiOx)-based inorganic layer, but the present disclosure is not limited thereto.

Each of ninth vias VA9 may penetrate the ninth insulating layer INS9 and may be connected to an exposed eighth conductive layer ML8. The ninth vias VA9 may be made of copper (Cu), aluminum (AI), tungsten (W), molybdenum (Mo), chromium (Cr), gold (Au), titanium (Ti), nickel (Ni) and/or neodymium (Nd) and/or may be made of an alloy including one or more of the same. A thickness of the ninth vias VA9 may be about 16500 Å.

The display element layer EML may be disposed on the light emitting element backplane EBP. The display element layer EML may include a reflective electrode layer RL, tenth and eleventh insulating layers INS10 and INS11, tenth vias VA10, light emitting elements LE, each including a first electrode AND, a light emitting stack IL and a second electrode CAT, a pixel defining layer PDL, and a plurality of trenches TRC.

The reflective electrode layer RL may be disposed on the ninth insulating layer INS9. The reflective electrode layer RL may include one or more reflective electrodes RL1 through RL4. For example, the reflective electrode layer RL may include first through fourth reflective electrodes RL1 through RL4 as illustrated in FIG. 7.

Each of the first reflective electrodes RL1 may be disposed on the ninth insulating layer INS9 and may be connected to a ninth via VA9. The first reflective electrodes RL1 may be made of copper (Cu), aluminum (AI), tungsten (W), molybdenum (Mo), chromium (Cr), gold (Au), titanium (Ti), nickel (Ni) and/or neodymium (Nd) or may be made of an alloy including one or more of the same. For example, the first reflective electrodes RL1 may include titanium nitride (TiN).

Each of the second reflective electrodes RL2 may be disposed on a first reflective electrode RL1. The second reflective electrodes RL2 may be made of copper (Cu), aluminum (AI), tungsten (W), molybdenum (Mo), chromium (Cr), gold (Au), titanium (Ti), nickel (Ni) and/or neodymium (Nd) and/or may be made of an alloy including one or more of the same. For example, the second reflective electrodes RL2 may include aluminum (AI).

Each of the third reflective electrodes RL3 may be disposed on a second reflective electrode RL2. The third reflective electrodes RL3 may be made of copper (Cu), aluminum (AI), tungsten (W), molybdenum (Mo), chromium (Cr), gold (Au), titanium (Ti), nickel (Ni) and//or neodymium (Nd) or may be made of an alloy including one or more of the same. For example, the third reflective electrodes RL3 may include titanium nitride (TiN).

Each of the fourth reflective electrodes RL4 may be disposed on a third reflective electrode RL3. The fourth reflective electrodes RL4 may be made of copper (Cu), aluminum (AI), tungsten (W), molybdenum (Mo), chromium (Cr), gold (Au), titanium (Ti), nickel (Ni) and/or neodymium (Nd) or may be made of an alloy including one or more of the same. For example, the fourth reflective electrodes RL4 may include titanium (Ti).

Because, in one or more embodiments, the second reflective electrodes RL2 are electrodes that substantially reflect light from the light emitting elements LE, a thickness of the second reflective electrodes RL2 may be greater than a thickness of the first reflective electrodes RL1, a thickness of the third reflective electrodes RL3, and a thickness of the fourth reflective electrodes RL4. For example, the thickness of the first reflective electrodes RL1, the thickness of the third reflective electrodes RL3 and the thickness of the fourth reflective electrodes RL4 may be about 100 Å, and the thickness of the second reflective electrodes RL2 may be about 850 Å. However, in one or more other embodiments, the fourth reflective electrodes RL4 may substantially reflect light from the light emitting elements LE and a thickness of the fourth reflective electrodes RL4 may be greater than a thickness of the first reflective electrodes RL1, a thickness of the second reflective electrodes RL2, and a thickness of the third reflective electrodes RL3.

The tenth insulating layer INS10 may be disposed on the ninth insulating layer INS9. The tenth insulating layer INS10 may be disposed between reflective electrode layers RL adjacent to each other in a horizontal direction. In one or more embodiments, the tenth insulating layer INS10 may be disposed on the reflective electrode layer RL in a third subpixel SP3. The tenth insulating layer INS10 may be a silicon oxide (SiOx)-based inorganic layer, but the present disclosure is not limited thereto.

The eleventh insulating layer INS11 may be disposed on the tenth insulating layer INS10 and the reflective electrode layer RL. The eleventh insulating layer INS11 may be a silicon oxide (SiOx)-based inorganic layer, but the present disclosure is not limited thereto. The tenth insulating layer INS10 and the eleventh insulating layer INS11 may be optical auxiliary layers through which light reflected by the reflective electrode layer RL from among light emitted from the light emitting elements LE passes.

A thickness of the eleventh insulating layer INS11 may be different in each of a first subpixel SP1, a second subpixel SP2 and the third subpixel SP3, in order to match resonance distances of light emitted from the light emitting elements LE. For example, a thickness of the eleventh insulating layer INS11 in a first subpixel SP1 may be smaller than a thickness of the eleventh insulating layer INS11 in a second subpixel SP2, and a thickness of the eleventh insulating layer INS11 in a second subpixel SP1 may be smaller than a thickness of the eleventh insulating layer INS11 in a third subpixel SP2

In summary, a distance between the first electrode AND and the reflective electrode layer RL may be different in each of the first subpixel SP1, the second subpixel SP2, and the third subpixel SP3. That is, the presence or absence of the tenth insulating layer INS10 and the eleventh insulating layer INS11 in each of the first subpixel SP1, the second subpixel SP2, and the third subpixel SP3 may be set in order to adjust the distance from the reflective electrode layer RL to the second electrode CAT according to the main wavelength of light emitted from each of the first subpixel SP1, the second subpixel SP2, and the third subpixel SP3. For example, in FIG. 7, a distance between the first electrode AND and the reflective electrode layer RL in the third subpixel SP3 may be greater than a distance between the first electrode AND and the reflective electrode layer RL in the second subpixel SP2 and a distance between the first electrode AND and the reflective electrode layer RL in the first subpixel SP1, and the distance between the first electrode AND and the reflective electrode layer RL in the second subpixel SP2 may be greater than the distance between the first electrode AND and the reflective electrode layer RL in the first subpixel SP1. However, the present disclosure is not limited thereto.

In addition, although the tenth insulating layer INS10 and the eleventh insulating layer INS11 are shown for example in embodiments of the present specification, a twelfth insulating layer disposed under the first electrode AND of the first subpixel SP1 may also be added. In this case, the eleventh insulating layer INS11 and the twelfth insulating layer may be disposed under the first electrode AND of the second subpixel SP2, and the tenth insulating layer INS10, the eleventh insulating layer INS11 and the twelfth insulating layer may be disposed under the first electrode AND of the third subpixel SP3.

In one or more embodiments, the tenth vias VA10 may penetrate the tenth insulating layer INS10 and/or the eleventh insulating layer INS11 in each of the first subpixel SP1, the second subpixel SP2, and the third subpixel SP3 and may be connected to the exposed fourth reflective electrodes RL4, respectively. The tenth vias VA10 may be made of copper (Cu), aluminum (AI), tungsten (W), molybdenum (Mo), chromium (Cr), gold (Au), titanium (Ti), nickel (Ni) and/or neodymium (Nd) or may be made of an alloy including one or more of the same. A thickness of a tenth via VA10 in the second subpixel SP2 may be smaller than a thickness of a tenth via VA10 in the third subpixel SP3.

The first electrode AND of each of the light emitting elements LE may be disposed on the eleventh insulating layer INS11 and may be connected to a tenth via VA10. The first electrode AND of each of the light emitting elements LE may be connected to the drain area DA or the source area SA of a pixel transistor PTR through a tenth via VA10, the first through fourth reflective electrodes RL1 through RL4, the first through ninth vias VA1 through VA9, the first through eighth conductive layers ML1 through ML8, and a contact terminal CTE. The first electrode AND of each of the light emitting elements LE may be made of copper (Cu), aluminum (AI), tungsten (W), molybdenum (Mo), chromium (Cr), gold (Au), titanium (Ti), nickel (Ni) and/or neodymium (Nd) or may be made of an alloy including one or more of the same. For example, the first electrode AND of each of the light emitting elements LE may be titanium nitride (TiN).

The pixel defining layer PDL may be disposed on a portion of the first electrode AND of each of the light emitting elements LE. The pixel defining layer PDL may cover edges of the first electrode AND of each of the light emitting elements LE. The pixel defining layer PDL defines first through third emission areas EA1 through EA3.

The first emission area EA1 may be defined as an area where the first electrode AND, the light emitting stack IL, and the second electrode CAT are sequentially stacked to emit light in the first subpixel SP1. The second emission area EA2 may be defined as an area where the first electrode AND, the light emitting stack IL, and the second electrode CAT are sequentially stacked to emit light in the second subpixel SP2. The third emission area EA3 may be defined as an area where the first electrode AND, the light emitting stack IL, and the second electrode CAT are sequentially stacked to emit light in the third subpixel SP3.

The pixel defining layer PDL may include first through third pixel defining layers PDL1 through PDL3. The first pixel defining layer PDL1 may be disposed on the edges of the first electrode AND of each of the light emitting elements LE. The second pixel defining layer PDL2 may be disposed on the first pixel defining layer PDL1. The third pixel defining layer PDL3 may be disposed on the second pixel defining layer PDL2. Each of the first pixel defining layer PDL1, the second pixel defining layer PDL2, and the third pixel defining layer PDL3 may be a silicon oxide (SiOx)-based inorganic layer, but the present disclosure is not limited thereto. A thickness of the first pixel defining layer PDL1, a thickness of the second pixel defining layer PDL2, and a thickness of the third pixel defining layer PDL3 may each be about 500 Å.

When the first pixel defining layer PDL1, the second pixel defining layer PDL2, and the third pixel defining layer PDL3 are formed as a single pixel defining layer, a height of the single pixel defining layer may be high, causing a first encapsulating inorganic layer TFE1 to be broken due to step coverage. The step coverage refers to the ratio of the degree to which a thin film is coated on an inclined portion to the degree to which the thin film is coated on a flat portion. The lower the step coverage, the higher the possibility that the thin film will be broken on the inclined portion.

Therefore, in order to prevent the first encapsulating inorganic layer TFE1 from being broken due to the step coverage, the first pixel defining layer PDL1, the second pixel defining layer PDL2, and the third pixel defining layer PDL3 may have a cross-sectional structure having steps. For example, a width of the first pixel defining layer PDL1 may be greater than a width of the second pixel defining layer PDL2 and a width of the third pixel defining layer PDL3, and the width of the second pixel defining layer PDL2 may be greater than the width of the third pixel defining layer PDL3. The width of the first pixel defining layer PDL1 refers to a horizontal length of the first pixel defining layer PDL1 defined by the first direction DR1 and the second direction DR2.

Each of the trenches TRC may penetrate the first pixel defining layer PDL1, the second pixel defining layer PDL2, and the third pixel defining layer PDL3. In addition, each of the trenches TRC may penetrate the eleventh insulating layer INS11. A portion of the eleventh insulating layer INS11 may have a recessed shape in each of the trenches TRC.

At least one trench TRC may be disposed between neighboring subpixels SP1 through SP3. Although two trenches TRC are disposed between the neighboring subpixels SP1 through SP3 in FIG. 7, the present disclosure is not limited thereto.

The light emitting stack IL may include a plurality of intermediate layers. In FIG. 7, the light emitting stack IL has a three-tandem structure including a first stack layer IL1, a second stack layer IL2, and a third stack layer IL3. However, the present disclosure is not limited thereto. For example, the light emitting stack IL may also have a two-tandem structure including two intermediate layers.

In the three-tandem structure, the light emitting stack IL may have a tandem structure including a plurality of stack layers IL1 through IL3 that emit different lights. For example, the light emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer emitting light of the first color, and a first electron transport layer are sequentially stacked. The second stack layer IL2 may have a structure in which a second hole transport layer, a second organic light emitting layer emitting light of the third color, and a second electron transport layer are sequentially stacked. The third stack layer IL3 may have a structure in which a third hole transport layer, a third organic light emitting layer emitting light of the second color, and a third electron transport layer are sequentially stacked.

A first charge generation layer may be disposed between the first stack layer IL1 and the second stack layer IL2 to supply charges to the second stack layer IL2 and electrons to the first stack layer IL1. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer may be disposed between the second stack layer IL2 and the third stack layer IL3 to supply charges to the third stack layer IL3 and electrons to the second stack layer IL2. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL and may be disposed on a bottom surface of each of the trenches TRC. Due to the trenches TRC, the first stack layer IL1 may be broken between neighboring subpixels SP1 through SP3. The second stack layer IL2 may be disposed on the first stack layer IL1. Due to the trenches TRC, the second stack layer IL2 may be broken between the neighboring subpixels SP1 through SP3. A void ESS or an empty space may be disposed in each of the trenches TRC. The third stack layer IL3 may be disposed on the second stack layer IL2. The third stack layer IL3 may not be broken by the trenches TRC and may cover the second stack layer IL2 in each of the trenches TRC. That is, in the three-tandem structure, each of the trenches TRC may be a structure for interrupting the first and second stack layers IL1 and IL2, the first charge generation layer, and the second charge generation layer of the display element layer EML between the neighboring subpixels SP1 through SP3. In addition, in the two-tandem structure, each of the trenches TRC may be a structure for interrupting a charge generation layer disposed between a lower intermediate layer and an upper intermediate layer and interrupting the lower intermediate layer.

In order to stably interrupt the first and second stack layers IL1 and IL2 of the display element layer EML between the neighboring subpixels SP1 through SP3, a height of each of the trenches TRC may be greater than a height of the pixel defining layer PDL. The height of each of the trenches TRC refers to a length of each of the trenches TRC in the third direction DR3. The height of the pixel defining layer PDL refers to a length of the pixel defining layer PDL in the third direction DR3. In order to interrupt the first and second stack layers IL1 and IL2 of the display element layer EML between the neighboring subpixels SP1 through SP3, another structure may exist instead of the trenches TRC. For example, instead of the trenches TRC, reverse tapered barrier ribs may be disposed on the pixel defining layer PDL.

The number of stack layers IL1 through IL3 emitting different lights is not limited to that illustrated in FIG. 7. For example, the light emitting stack IL may include two intermediate layers. In this case, any one of the two intermediate layers may be substantially the same as the first stack layer IL1, and the other one may include a second hole transport layer, a second organic light emitting layer, a third organic light emitting layer, and a second electron transport layer. In this case, a charge generation layer may be disposed between the two intermediate layers to supply electrons to any one of the two intermediate layers and to supply charges to the other intermediate layer.

In addition, in FIG. 7, the first through third stack layers IL1 through IL3 are disposed in all of the first emission area EA1, the second emission area EA2, and the third emission area EA3. However, the present disclosure is not limited thereto. For example, the first stack layer IL1 may be disposed in the first emission area EA1 and may not be disposed in the second emission area EA2 and the third emission area EA3. In addition, the second stack layer IL2 may be disposed in the second emission area EA2 and may not be disposed in the first emission area EA1 and the third emission area EA3. In addition, the third stack layer IL3 may be disposed in the third emission area EA3 and may not be disposed in the first emission area EA1 and the second emission area EA2. In this case, first through third color filters CF1 through CF3 of the optical layer OPL may be omitted.

The second electrode CAT may be disposed on the third stack layer IL3. The second electrode CAT may be disposed on the third stack layer IL3 in each of the trenches TRC. The second electrode CAT may be made of a transparent conductive material (TCO) that can transmit light, such as indium tin oxide (ITO) and/or indium zinc oxide (IZO), or a semi-transmissive conductive material such as magnesium (Mg), silver (Ag) or an alloy of Mg and Ag. When the second electrode CAT is made of a semi-transmissive conductive material, the light output efficiency of each of the first through third subpixels SP1 through SP3 may be increased by a microcavity.

The encapsulation layer TFE may be disposed on the display element layer EML. The encapsulation layer TFE may include one or more inorganic layers TFE1 and TFE2 to prevent the penetration of oxygen and/or moisture into the display element layer EML. For example, the encapsulation layer TFE may include the first encapsulating inorganic layer TFE1 and a second encapsulating inorganic layer TFE2.

The first encapsulating inorganic layer TFE1 may be disposed on the second electrode CAT. The first encapsulating inorganic layer TFE1 may be a multilayer in which one or more inorganic layers selected from silicon nitride (SiNx), silicon oxynitride (SiON), and/or silicon oxide (SiOx) are alternately stacked. The first encapsulating inorganic layer TFE1 may be formed by a chemical vapor deposition (CVD) process.

The second encapsulating inorganic layer TFE2 may be disposed on the first encapsulating inorganic layer TFE1. The second encapsulating inorganic layer TFE2 may be a titanium oxide (TiOx) and/or aluminum oxide (AIOx) layer, but the present disclosure is not limited thereto. The second encapsulating inorganic layer TFE2 may be formed by an atomic layer deposition (ALD) process. A thickness of the second encapsulating inorganic layer TFE2 may be smaller than a thickness of the first encapsulating inorganic layer TFE1.

An organic layer APL may be a layer for increasing the interfacial adhesion between the encapsulation layer TFE and the optical layer OPL. The organic layer APL may be an organic layer such as acryl resin, epoxy resin, phenolic resin, polyamide resin, and/or polyimide resin.

The optical layer OPL includes a plurality of color filters CF1 through CF3, a plurality of lenses LNS, and a filling layer FIL. The color filters CF1 through CF3 may include the first through third color filters CF1 through CF3. The first through third color filters CF1 through CF3 may be disposed on the organic layer APL.

The first color filter CF1 may overlap the first emission area EA1 of the first subpixel SP1. The first color filter CF1 may transmit light of the first color, that is, light in the blue wavelength band. The blue wavelength band may be about 370 to 460 nm. Therefore, the first color filter CF1 can transmit the light of the first color from among the light emitted from the first emission area EA1.

The second color filter CF2 may overlap the second emission area EA2 of the second subpixel SP2. The second color filter CF2 may transmit light of the second color, that is, light in the green wavelength band. The green wavelength band may be about 480 to 560 nm. Therefore, the second color filter CF2 can transmit the light of the second color from among the light emitted from the second emission area EA2.

The third color filter CF3 may overlap the third emission area EA3 of the third subpixel SP3. The third color filter CF3 may transmit light of the third color, that is, light in the red wavelength band. The red wavelength band may be about 600 to 750 nm. Therefore, the third color filter CF3 can transmit the light of the third color from among the light emitted from the third emission area EA3.

The lenses LNS may be disposed on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape.

The filling layer FIL may be disposed on the lenses LNS. The filling layer FIL may have a suitable refractive index (e.g., a predetermined refractive index) so that light can travel in the third direction DR3 at an interface between the lenses LNS and the filling layer FIL. In addition, the filling layer FIL may be a planarization layer. The filling layer FIL may be an organic layer such as acryl resin, epoxy resin, phenolic resin, polyamide resin, and/or polyimide resin.

The cover layer CVL may be disposed on the filling layer FIL. The cover layer CVL may be a glass substrate and/or a polymer resin such as resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin such as resin, it may be directly applied on the filling layer FIL.

The polarizing plate POL may be disposed on a surface of the cover layer CVL. The polarizing plate POL may be a structure for preventing visibility reduction due to the reflection of external light. The polarizing plate POL may include a linear polarizing plate and a phase retardation film. For example, the phase retardation film may be a quarter-wave plate (λ/4 plate), but the present disclosure is not limited thereto. If visibility due to the reflection of external light is sufficiently improved by the first through third color filters CF1 through CF3, the polarizing plate POL may be omitted.

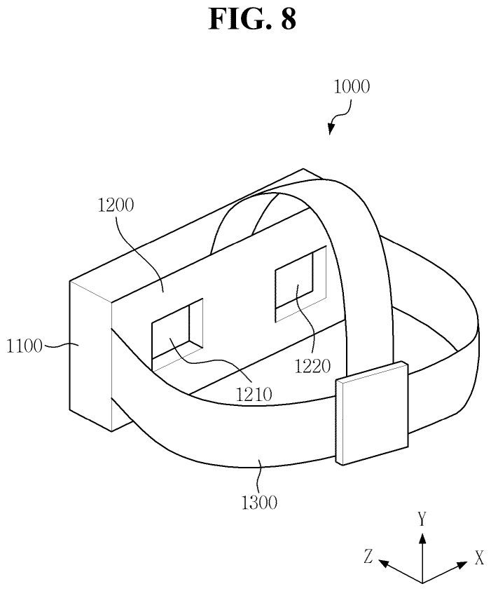

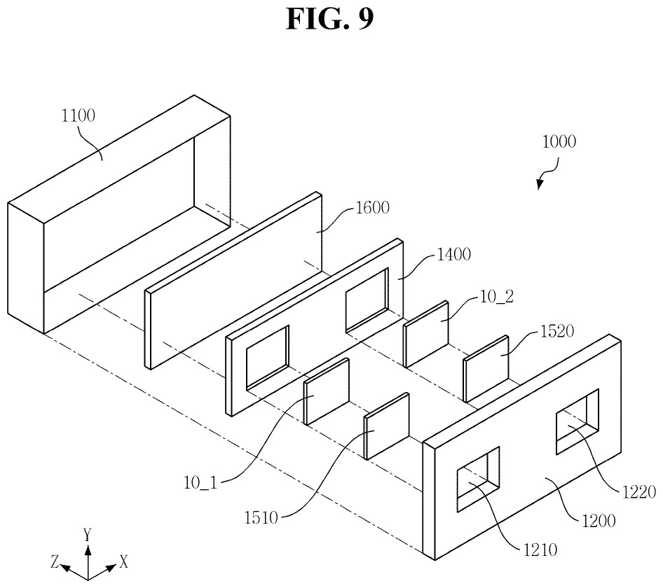

FIG. 8 is a perspective view of a head mounted display device 1000 according to one or more embodiments. FIG. 9 is an exploded perspective view of an example of the head mounted display device 1000 of FIG. 8.

Referring to FIGS. 8 and 9, the head mounted display device 1000 according to the embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to the user's right eye. Each of the first display device 10_1 and the second display device 10_2 is substantially the same as the display device 10 described with reference to FIGS. 1 and 2. Therefore, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 supports and fixes the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source received from the outside into digital video data DATA and transmit the digital video data DATA to the first display device 10_1 and the second display device 10_2 through the connector.

The control circuit board 1600 may transmit the digital video data DATA corresponding to a left image optimized for a user's left eye to the first display device 10_1 and transmit the digital video data DATA corresponding to a right image optimized for the user's right eye to the second display device 10_2. Alternatively, the control circuit board 1600 may transmit the same digital video data DATA to the first display device 10_1 and the second display device 10_2.

The display device housing 1100 houses the first display device 10_1, the second display device 10_2, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 8 and 9, the present disclosure is not limited thereto. The first eyepiece 1210 and the second eyepiece 1220 may also be combined into one.

The first eyepiece 1210 may be aligned with the first display device 10_1 and the first optical member 1510, and the second eyepiece 1220 may be aligned with the second display device 10_2 and the second optical member 1520. Therefore, a user can view an image of the first display device 10_1, which is enlarged as a virtual image by the first optical member 1510, through the first eyepiece 1210 and can view an image of the second display device 10_2, which is enlarged as a virtual image by the second optical member 1520, through the second eyepiece 1220.

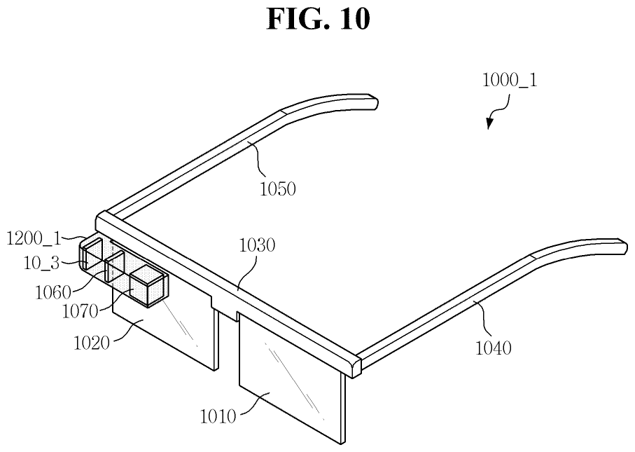

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000 may include an eyeglass frame as illustrated in FIG. 10 instead of the head mounted band 1300.

In addition, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view of a head mounted display device 1000_1 according to one or more embodiments.

Referring to FIG. 10, the head mounted display device 1000_1 according to the embodiment may be a display device in the form of glasses in which a display device housing 1200_1 is implemented to be lightweight and small. The head mounted display device 1000_1 according to the embodiment may include a display device 10_3, a left lens 1010, a right lens 1020, a support frame 1030, eyeglass frame legs 1040 and 1050, an optical member 1060, an optical path conversion member 1070, and the display device housing 1200_1.

The display device housing 1200_1 may include the display device 10_3, the optical member 1060, and the optical path conversion member 1070. An image displayed on the display device 10_3 may be enlarged by the optical member 1060, may have its optical path converted by the optical path conversion member 1070, and then may be provided to a user's right eye through the right lens 1020. Accordingly, the user can view, through the right eye, an augmented reality image into which a virtual image displayed on the display device 10_3 and a real image viewed through the right lens 1020 are combined.

Although the display device housing 1200_1 is disposed at a right end of the support frame 1030 in FIG. 10, the present disclosure is not limited thereto. For example, the display device housing 1200_1 may also be disposed at a left end of the support frame 1030. In this case, an image of the display device 10_3 may be provided to a user's left eye. Alternatively, the display device housing 1200_1 may be disposed at both the left and right ends of the support frame 1030. In this case, the user can view an image displayed on the display device 10_3 through both the left and right eyes.

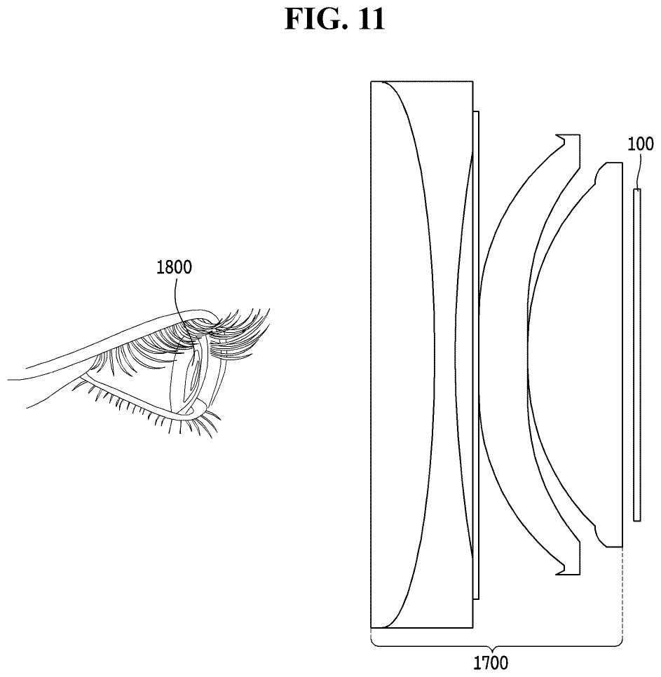

FIG. 11 illustrates a configuration of a display device including a pancake lens unit 1700 according to one or more embodiments.

Referring to FIG. 11, the display device according to the embodiment includes a display panel 100 and the pancake lens unit 1700 disposed on the display panel 100.

The pancake lens unit 1700 is an optical element that selectively transmits or reflects light output from the display panel 100 by using a linear polarizing plate, a half mirror, a reflective polarizing plate, and a phase difference film. The pancake lens unit 1700 may include about three or more lenses, about two or more quarter-wave plates (QWPs), a half mirror, about one or more reflective polarizing plates, and about one or more absorbing polarizing plates. Because the pancake lens unit 1700 uses a method of folding an optical path, it can implement an optical module with a smaller thickness than a Fresnel lens.

When light output from the display panel 100 passes through the pancake lens unit 1700 and travels to a user 1800, a chief ray angle (CRA) characteristic of a lens included in the pancake lens unit 1700 may cause a difference in the luminance efficiency of the display panel 100. For example, the CRA characteristic refers to an angle formed by an optical axis and a chief ray with respect to a center of the lens.

A plurality of lenses LNS (see FIG. 7) included in an optical layer OPL (see FIG. 7) of the display panel 100 may be designed to have a different shape in each part of the display panel 100 in consideration of the CRA characteristic of the pancake lens unit 1700.

The lenses LNS included in the optical layer OPL of the display panel 100 may be designed to have a different shift distance in each part of the display panel 100 in consideration of the CRA characteristic of the pancake lens unit 1700. Here, the shift distance of a lens LNS refers to a distance between a virtual line passing through a center of the lens LNS and a virtual line passing through a center of a subpixel (e.g., SP1, SP2, SP3) when the lens LNS and the subpixel (e.g., SP1, SP2, SP3) overlap. For example, the shorter the shift distance of the lens LNS, the smaller the distance between the virtual line passing through the center of the lens LNS and the virtual line passing through the center of the subpixel (e.g., SP1, SP2, SP3).

Because the lenses LNS included in the optical layer OPL of the display panel 100 are designed to have a different shape and shift distance in each part of the display panel 100 in consideration of the CRA characteristic of the pancake lens unit 1700, it is possible to increase luminance efficiency and reduce color crosstalk.

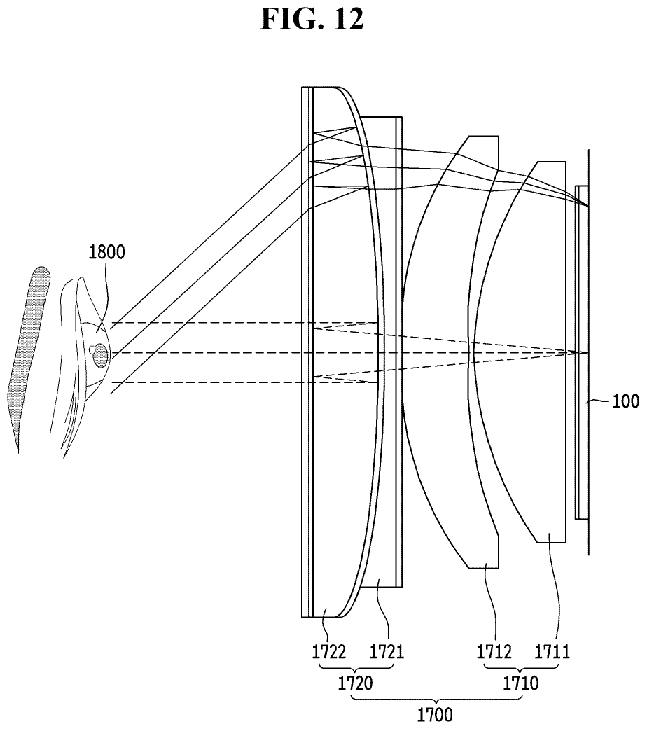

FIG. 12 illustrates the configuration of the pancake lens unit 1700 according to one or more embodiments.

Referring to FIG. 12, the pancake lens unit 1700 disposed on the display panel 100 according to the embodiment includes at least one first pancake lens element 1710 including a plastic material and at least one second pancake lens element 1720 including a glass material.

The at least one first pancake lens element 1710 is disposed between the display panel 100 and the at least one second pancake lens element 1720.

The at least one first pancake lens element 1710 includes a first pancake lens 1711 and a second pancake lens 1712 overlapping each other. The first pancake lens 1711 and the second pancake lens 1712 may be aspherical lenses and may be lenses made of a plastic material.

The material of each of the first pancake lens 1711 and the second pancake lens 1712 may include plastic. For example, each of the first pancake lens 1711 and the second pancake lens 1712 may include polyester-based plastic and/or cyclo olefin polymer (COP)-based plastic.

The at least one second pancake lens element 1720 includes a third pancake lens 1721 and a fourth pancake lens 1722 overlapping each other.

A half mirror is disposed between the third pancake lens 1721 and the fourth pancake lens 1722.

The material of each of the third pancake lens 1721 and the fourth pancake lens 1722 may include glass. For example, each of the third pancake lens 1721 and the fourth pancake lens 1722 may include glass having a refractive index of about 1.9 or more.

In the present specification, a refractive index refers to an absolute refractive index measured using a D line (wavelength λ of about 589 nm: yellow) of natrium (or sodium) at room temperature and humidity (a temperature of 20±15° C. and a humidity of 65±20%). For example, in the present specification, the refractive index may be an absolute refractive index measured based on a wavelength of 589 nm according to a Cauchy film model using a refractive index measuring device (e.g., ellipsometer (ellipsometer M-2000, J. A. Woollam)) under 25° C. and a relative humidity of 65%.

When lenses of the pancake lens unit 1700 are configured, if the lenses include only spherical lenses made of glass, image distortion can be reduced or minimized, but the number of lenses may increase, thus increasing a total thickness of an optical module.

When the lenses of the pancake lens unit 1700 are configured, if the lenses include only aspherical lenses made of plastic, the number of lenses can be reduced, but image distortion may increase. For example, if the lenses include only aspherical lenses made of plastic, the birefringence of the lenses and the appearance of unintended ghost images can occur.

According to one or more embodiments, because the first pancake lens element 1710 is made of a plastic material and the second pancake lens element 1720 is made of a glass material, the total thickness of the optical module can be reduced, while the birefringence of the lenses and the appearance of unintended ghost images are reduced or minimized.

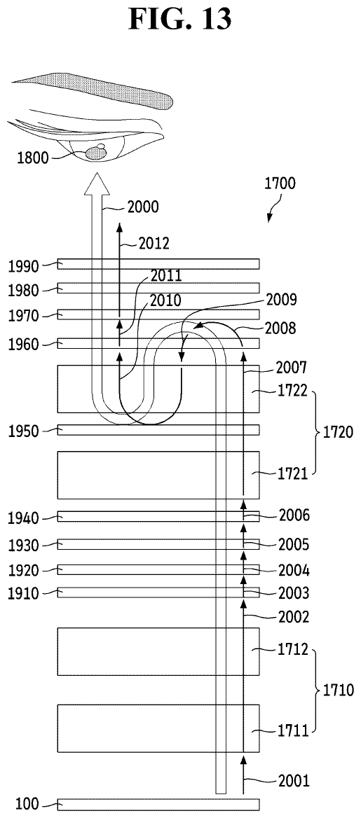

FIG. 13 illustrates the stacked structure of the pancake lens unit 1700 according to one or more embodiments.

Referring to FIG. 13, the pancake lens unit 1700 according to the embodiment includes the first pancake lens element 1710 disposed on the display panel 100 and the second pancake lens element 1720 disposed on the first pancake lens element 1710.

A first anti-reflection film 1910, a first QWP 1920, a first polarizing film 1930, and a second QWP 1940 are disposed between at least one first pancake lens element 1710 and at least one second pancake lens element 1720.

The first pancake lens element 1710 includes the first pancake lens 1711 and the second pancake lens 1712 overlapping each other. The material of each of the first pancake lens 1711 and the second pancake lens 1712 may include plastic. For example, each of the first pancake lens 1711 and the second pancake lens 1712 may include polyester-based plastic and/or cyclo olefin polymer (COP)-based plastic.

The second pancake lens element 1720 includes the third pancake lens 1721 and the fourth pancake lens 1722 overlapping each other. The material of each of the third pancake lens 1721 and the fourth pancake lens 1722 may include glass. For example, each of the third pancake lens 1721 and the fourth pancake lens 1722 may include glass having a refractive index of about 1.9 or more.

A half mirror 1950 is disposed between the third pancake lens 1721 and the fourth pancake lens 1722.

A third QWP 1960, a second polarizing film 1970, a third polarizing film 1980, and a second anti-reflection film 1990 are disposed on at least one second pancake lens element 1720.

The second polarizing film 1970 is a reflective polarizing film, and the third polarizing film 1980 is an absorbing polarizing film.

The path and polarization state of light output from the display panel 10 according to the embodiment will now be described.

Light output from the display panel 100 may be unpolarized light and may be provided to a user via the pancake lens unit 1700 along a path indicated by arrow 2000 of FIG. 13. The path of light according to arrow 2000 will be described in detail as follows.

Referring to arrow 2001, unpolarized light may be emitted from the display panel 100.

Referring to arrow 2002, the unpolarized light emitted from the display panel 100 may remain unpolarized without a change in its polarization state even after passing through the first pancake lens element 1710. The unpolarized light emitted from the display panel 100 may have its image magnified as it passes through the first pancake lens element 1710.

Referring to arrow 2003, the unpolarized light passing through the first pancake lens element 1710 may remain unpolarized without a change in its polarization state even after passing through the first anti-reflection film 1910.

Referring to arrow 2004, the unpolarized light passing through the first anti-reflection film 1910 may become circularly polarized or elliptically polarized as it passes through the first QWP 1920. For example, if an optical axis of the first QWP 1920 is inclined at +45 degrees with respect to a vertical direction, the unpolarized light passing through the first anti-reflection film 1910 may become right-circularly polarized. If the optical axis of the first QWP 1920 is inclined at −45 degrees with respect to the vertical direction, the unpolarized light passing through the first anti-reflection film 1910 may become left-circularly polarized.

The first QWP 1920 may prevent external light from being reflected by the display panel 100 and emitted toward the user 1800. For example, as indicated by arrow 2007 to be described below, some of the left-polarized light passing through the second QWP 1940 may pass through the half mirror 1950, but some may be reflected by the half mirror 1950 to move back toward the display panel 100. In addition, as indicated by arrow 2010 to be described below, some of the light reflected from the second polarizing film 1970 may be reflected by the half mirror 1950, but some may pass through the half mirror 1950 and move back toward the display panel 100. The first QWP 1920 may prevent such light from entering the display panel 100.

Referring to arrow 2005, the circularly or elliptically polarized light passing through the first QWP 1920 may become vertically polarized or horizontally polarized as it passes through the first polarizing film 1930. For example, if an optical axis of the first polarizing film 1930 is the vertical direction, the circularly or elliptically polarized light passing through the first QWP 1920 may become vertically polarized, and if the optical axis of the first polarizing film 1930 is the horizontal direction, the circularly or elliptically polarized light passing through the first QWP 1920 may become horizontally polarized. A case where the circularly or elliptically polarized light passing through the first QWP 1920 becomes vertically polarized (a case where the optical axis of the first polarizing film 1930 is the vertical direction) will be described as an example below.

Referring to arrow 2006, the vertically polarized light passing through the first polarizing film 1930 may become circularly polarized or elliptically polarized as it passes through the second QWP 1940. For example, if an optical axis of the second QWP 1940 is inclined at +45 degrees with respect to the vertical direction, the vertically polarized light passing through the first polarizing film 1930 may become right-circularly polarized, and if the optical axis of the second QWP 1940 is inclined at −45 degrees with respect to the vertical direction, the vertically polarized light passing through the first polarizing film 1930 may become left-circularly polarized. A case where the vertically polarized light passing through the first polarizing film 1930 becomes left-circularly polarized (a case where the optical axis of the second QWP 1940 is inclined at −45 degrees with respect to the vertical direction) will be described as an example below.

Referring to arrow 2007, the left-circularly polarized light passing through the second QWP 1940 may remain left-circularly polarized without a change in its polarization state even after passing through the second pancake lens element 1720 and the half mirror 1950. In one or more embodiments, some of the left-circularly polarized light passing through the second QWP 1940 may pass through the half mirror 1950, and some may be reflected.

Referring to arrow 2008, the left-circularly polarized light passing through the second pancake lens element 1720 and the half mirror 1950 may become vertically polarized as it passes through the third QWP 1960. The third QWP 1960 may have an optical axis inclined at a different angle from that of the second QWP 1940. For example, the third QWP 1960 may have an optical axis inclined at +45 degrees with respect to the vertical direction. Accordingly, the left-circularly polarized light may become vertically polarized as it passes through the third QWP 1960.

The vertically polarized light passing through the third QWP 1960 may be reflected by the second polarizing film 1970. The second polarizing film 1970 may be a reflective polarizing film, and its polarization axis may extend in the horizontal direction. Accordingly, the second polarizing film 1970 may reflect vertically polarized light and transmit horizontally polarized light. Therefore, the vertically polarized light passing through the third QWP 1960 may be reflected by the second polarizing film 1970. At this time, the vertically polarized light passing through the third QWP 1960 may be reflected as it is by the second polarizing film 1970 without a change in its polarization state.

Referring to arrow 2009, the vertically polarized light reflected by the second polarizing film 1970 may become left-circularly polarized as it passes through the third QWP 1960. As described with reference to arrow 2006, the vertically polarized light passing through the first polarizing film 1930 is converted into left-circularly polarized light as it passes upward through the second QWP 1940 having an optical axis inclined at −45 degrees with respect to the vertical direction. On the other hand, the vertically polarized light reflected by the second polarizing film 1970 may be converted into left-circularly polarized light as it passes downward through the third QWP 1960 having an optical axis inclined at +45 degrees with respect to the vertical direction.

Referring to arrow 2010, some of the left-circularly polarized light passing through the third QWP 1960 may be reflected by the half mirror 1950 and converted into right-circularly polarized light by a lateral inversion effect.

Referring to arrow 2011, the right-circularly polarized light reflected by the half mirror 1950 may become horizontally polarized as it passes through the third QWP 1960.

Referring to arrow 2012, the horizontally polarized light passing through the third QWP 1960 may pass, as it is, through the second polarizing film 1970 and the third polarizing film 1980 whose polarization axes extend in the horizontal direction. In addition, the horizontally polarized light passing through the second polarizing film 1970 and the third polarizing film 1980 may pass through the second anti-reflection film 1990 and may be provided to the user 1800.

Because the display device 10 according to the current embodiment includes folded optics, light passes through four lenses a total of six times. Therefore, the frequency of image magnification may increase, and the degree of image magnification may increase due to an increase in optical path. Accordingly, a thickness of the display device 10 can be reduced, but a more magnified image can be obtained.

In concluding the detailed description, those skilled in the art will appreciate that many variations and modifications can be made to the embodiments without substantially departing from the principles of the present disclosure. Therefore, the disclosed embodiments of the present disclosure are used in a generic and descriptive sense only and not for purposes of limitation.

What is claimed is:

1. A display device comprising:
a display panel, which comprises a display element layer comprising a light emitting element, an encapsulation layer on the display element layer, and an optical layer on the encapsulation layer, the optical layer comprising a plurality of lenses; and
a pancake lens unit on the display panel, the pancake lens unit comprising at least one first pancake lens element comprising a plastic material and at least one second pancake lens element comprising a glass material.

2. The display device of claim 1, wherein the at least one first pancake lens element is between the display panel and the at least one second pancake lens element.

3. The display device of claim 1, wherein the at least one first pancake lens element comprises a first pancake lens and a second pancake lens overlapping each other.

4. The display device of claim 3, wherein a material of each of the first pancake lens and the second pancake lens comprises at least one of polyester-based plastic and cyclo olefin polymer (COP)-based plastic.

5. The display device of claim 4, wherein the at least one second pancake lens element comprises a third pancake lens and a fourth pancake lens overlapping each other.

6. The display device of claim 5, wherein a half mirror is located between the third pancake lens and the fourth pancake lens.

7. The display device of claim 6, wherein a material of each of the third pancake lens and the fourth pancake lens comprises glass having a refractive index of about 1.9 or more.

8. The display device of claim 7, wherein a first anti-reflection film, a first quarter-wave plate (QWP), a first polarizing film, and a second QWP are between the at least one first pancake lens element and the at least one second pancake lens element.

9. The display device of claim 8, wherein a third QWP, a second polarizing film, a third polarizing film, and a second anti-reflection film are on the at least one second pancake lens element.

10. The display device of claim 9, wherein:
the second polarizing film is a reflective polarizing film; and
the third polarizing film is an absorbing polarizing film.

11. A mobile electronic device comprising:
a display panel, which comprises a display element layer comprising a light emitting element, an encapsulation layer on the display element layer, and an optical layer on the encapsulation layer, the optical layer comprising a plurality of lenses; and
a pancake lens unit on the display panel, the pancake lens unit comprising at least one first pancake lens element comprising a plastic material and at least one second pancake lens element comprising a glass material.

12. The mobile electronic device of claim 11, wherein the at least one first pancake lens element is between the display panel and the at least one second pancake lens element.

13. The mobile electronic device of claim 11, wherein the at least one first pancake lens element comprises a first pancake lens and a second pancake lens overlapping each other.

14. The mobile electronic device of claim 13, wherein a material of each of the first pancake lens and the second pancake lens comprises at least one of polyester-based plastic and cyclo olefin polymer (COP)-based plastic.

15. The mobile electronic device of claim 14, wherein the at least one second pancake lens element comprises a third pancake lens and a fourth pancake lens overlapping each other.

16. The mobile electronic device of claim 15, wherein a half mirror is located between the third pancake lens and the fourth pancake lens.

17. The mobile electronic device of claim 16, wherein a material of each of the third pancake lens and the fourth pancake lens comprises glass having a refractive index of about 1.9 or more.

18. The mobile electronic device of claim 17, wherein a first anti-reflection film, a first QWP, a first polarizing film, and a second QWP are between the at least one first pancake lens element and the at least one second pancake lens element.

19. The mobile electronic device of claim 18, wherein a third QWP, a second polarizing film, a third polarizing film, and a second anti-reflection film are on the at least one second pancake lens element.

20. The mobile electronic device of claim 19, wherein:
the second polarizing film is a reflective polarizing film; and
the third polarizing film is an absorbing polarizing film.
